(19) United States
(12) Patent Application Publication
(10) Pub. No.: US 2020/0186145 A1
(43) Pub. Date: Jun. 11, 2020

(54) GATE DRIVING CIRCUIT AND POWER SWITCHING SYSTEM

(71) Applicant: Panasonic Intellectual Property Management Co., Ltd., Osaka (JP)

(72) Inventors: Shuichi NAGAI, Osaka (JP); Shingo ENOMOTO, Osaka (JP); Noboru NEGORO, Osaka (JP); Yasufumi KAWAI, Osaka (JP); Songbaek CHOE, Osaka (JP); Osamu TABATA, Osaka (JP)

(21) Appl. No.: 16/793,970

(22) Filed: Feb. 18, 2020

Related U.S. Application Data
(63) Continuation of application No. PCT/JP2018/027229, filed on Jul. 20, 2018.

(30) Foreign Application Priority Data
Sep. 13, 2017 (JP) 2017-175942

(51) Int. Cl. H03K 17/567; H02M 7/217

(52) U.S. Cl. CPC H03K 17/567; H02M 7/217

(57) ABSTRACT

A gate driving circuit that controls a switching element includes: a startup switch which is provided between a gate voltage source and an output terminal; a termination switch which is provided between the output terminal and an output ground terminal; a startup resistor provided between a gate and a source of the startup switch; and a termination resistor provided between a gate and a source of the termination switch. At least one of the startup resistor or the termination resistor is configured to adjust a resistance value.

### CROSS REFERENCE TO RELATED APPLICATIONS

This application is a U.S. continuation application of PCT International Patent Application Number PCT/JP2018/027229 filed on Jul. 20, 2018, claiming the benefit of priority of Japanese Patent Application Number 2017-175942 filed on Sep. 13, 2017, the entire contents of which are hereby incorporated by reference.

### BACKGROUND

### 1. Technical Field

The present disclosure relates to a gate driving circuit that drives a semiconductor switching element.

### 2. Description of the Related Art

Inverters that switch electric power are widely used for common home appliances, such as air conditioners, washing machines, and refrigerators, industrial electrical equipment, such as power conditioners, and electric vehicles, for example. Such inverters each include a semiconductor switching element (hereinafter, also simply referred to as a “switching element”) which switches electric power, and a gate driving circuit for driving the semiconductor switching element. For example, a power semiconductor (power device) which can withstand high voltage, such as an insulated-gate bipolar transistor (IGBT), is used as the switching element. The gate driving circuit applies a gate voltage to the gate terminal of the switching element to switch on and off the switching element.

Here, the switching element typically operates at a high voltage that ranges from several tens of volts to several thousands of volts. On the contrary, a control signal for switching on and off the switching element is supplied from a control circuit which operates at several volts or less. In this case, the gate driving circuit needs to supply a driving signal to the switching element while securing electrical insulation between an output side on which the switching element is provided and an input side on which the control circuit is provided (this is called non-contact electric power transmission). Accordingly, an insulation signal transmission element (or a non-contact signal transmission element) is provided between the output side and the input side in the gate driving circuit.

For example, Japanese Unexamined Patent Application Publication No. 2008-67012 proposes, as such an insulation signal transmission element, an electric power transmission device which uses an electromagnetic resonance coupler in the shape of an open ring.

### SUMMARY

Conventionally, a gate resistor has been provided between a gate driving circuit and a switching element to adjust a slew rate at the time of switching operation. However, the provision of the gate resistor has been causing following problems.

First, the provision of the gate resistor causes an electrical distance between the gate driving circuit and the switching element, and thus a large amount of parasitic inductance is present. Because of this, ringing of a gate driving signal is caused.

In addition, the provision of the gate resistor causes what is called self turn-on that may cause a malfunction. The application of a negative gate voltage to the switching element for preventing the self turn-on when the switching element is switched off lengthens startup time and termination time, and also requires a large amount of driving power.

Furthermore, since a large current flows into the gate resistor, it was necessary to use a gate resistor that can withstand high resistance.

In view of the above, a gate driving circuit according to the present disclosure aims to enable adjustment of a slew rate at the time of switching operation, without providing a gate resistor.

A gate driving circuit according to an aspect of the present disclosure which controls a switching element includes: an output ground terminal; an output terminal from which a gate driving signal to be applied to the switching element is outputted; a startup switch which is provided between a gate voltage source and the output terminal, and includes one or more transistors; a termination switch which is provided between the output terminal and the output ground terminal, and includes one or more transistors; a startup resistor provided between a gate and a source of a transistor among the one or more transistors included in the startup switch; and a termination resistor provided between a gate and a source of a transistor among the one or more transistors included in the termination switch, wherein at least one of the startup resistor or the termination resistor is configured to adjust a resistance value.

The present disclosure enables adjustment of a slew rate at the time of switching operation, without providing a gate resistor.

### BRIEF DESCRIPTION OF DRAWINGS

These and other objects, advantages and features of the disclosure will become apparent from the following description thereof taken in conjunction with the accompanying drawings that illustrate a specific embodiment of the present disclosure.

FIG. 1 is a schematic diagram illustrating a configuration of a power switching system which includes a gate driving circuit according to Embodiment 1;

FIG. 2 is a graph illustrating a relation between a resistance value of a startup resistor, startup time, and delay time;

FIG. 3 is a schematic diagram illustrating another configuration example of the startup resistor and a termination resistor;

FIG. 4A is a schematic diagram illustrating a configuration example in which a capacitor is added to the termination resistor;

FIG. 4B is a schematic diagram illustrating a configuration example in which a capacitor is added to the termination resistor;

FIG. 4C is a schematic diagram illustrating a configuration example in which a capacitor is added to the termination resistor;

FIG. 5 is a schematic diagram illustrating a configuration example of the termination switch that includes a plurality of transistors;

FIG. 6 is a schematic diagram illustrating a configuration of a power switching system that includes a gate driving circuit according to a variation;

FIG. 7 illustrates a configuration example of a gate driving circuit whose configuration performs other than non-contact electric power transmission;

FIG. 8 is a diagram illustrating a configuration example of a power switching system which includes a gate driving circuit according to Embodiment 2;

FIG. 9 is a diagram illustrating a configuration example of a power switching system which includes a gate driving circuit according to Embodiment 3; and

FIG. 10 is a flowchart illustrating a method of adjusting a slew rate of a gate driving circuit according to an embodiment.

### DETAILED DESCRIPTION OF THE EMBODIMENTS OUTLINE

A gate driving circuit according to a first aspect of the present disclosure which controls a switching element includes: an output ground terminal; an output terminal from which a gate driving signal to be applied to the switching element is outputted; a startup switch which is provided between a gate voltage source and the output terminal, and includes one or more transistors; a termination switch which is provided between the output terminal and the output ground terminal, and includes one or more transistors; a startup resistor provided between a gate and a source of a transistor among the one or more transistors included in the startup switch; and a termination resistor provided between a gate and a source of a transistor among the one or more transistors included in the termination switch. In the gate driving circuit, at least one of the startup resistor or the termination resistor is configured to adjust a resistance value.

Accordingly, the adjustment of a resistance value of the startup resistor in the gate driving circuit makes it possible to shorten or lengthen the startup time of a gate driving signal. In addition, the adjustment of a resistance value of the termination resistor makes it possible to shorten or lengthen the termination time of a gate driving signal. Therefore, without providing a gate resistor between the gate driving circuit and the switching element, it is possible to adjust the slew rate of the switching element at the time of switching on and off the switching element.

In the gate driving circuit according to the first aspect of the present disclosure, at least one of the startup resistor or the termination resistor may include a variable resistor.

With this, at least one of the startup resistor and the termination resistor can be configured to adjust a resistance value.

In the gate driving circuit according to the first aspect of the present disclosure, at least one of the startup resistor or the termination resistor may be configured to accept an external resistor.

With this, at least one of the startup resistor and the termination resistor can be configured to adjust a resistance value. In addition, a gate voltage of the startup switch or the termination switch can be monitored from the external terminal to which the external resistor is added. The external resistor can be selected based on the gate voltage that has been monitored.

The gate driving circuit according to the first aspect of the present disclosure may further include a capacitor in parallel with at least one of the startup resistor or the termination resistor.

A gate driving circuit according to a second aspect of the present disclosure which controls a switching element includes: a transmission circuit that transmits a first signal and a second signal which are high frequency signals, and have binary-modulated amplitudes, the first signal and the second signal being complementarily modulated; a first coupler that performs insulated transmission of the first signal; a second coupler that performs insulated transmission of the second signal; an output ground terminal; an output terminal from which a gate driving signal to be applied to the switching element is outputted; a startup switch which is provided between a gate voltage source and the output terminal, and includes one or more transistors; a termination switch which is provided between the output terminal and the output ground terminal, and includes one or more transistors; a startup resistor provided between a gate and a source of a transistor among the one or more transistors included in the startup switch; a termination resistor provided between a gate and a source of a transistor among the one or more transistors included in the termination switch; a first rectifier that rectifies an output of the first coupler, and outputs a voltage for driving the startup switch; a second rectifier that rectifies an output of the second coupler, and outputs a voltage for driving the termination switch; and a crosstalk quantity adjuster that adjusts a crosstalk quantity between the first coupler and the second coupler.

Accordingly, in the gate driving circuit, the adjustment of a crosstalk quantity between the first coupler and the second coupler using the crosstalk quantity adjuster makes it possible to shorten or lengthen the startup time and the termination time of a gate driving signal. Therefore, without providing a gate resistor between the gate driving circuit and the switching element, it is possible to adjust the slew rate of the switching element at the time of switching on and off the switching element.

A gate driving circuit according to a third aspect of the present disclosure which controls a switching element includes: a transmission circuit that transmits a first signal and a second signal which are high frequency signals, and have binary-modulated amplitudes, the first signal and the second signal being complementarily modulated; a first coupler that performs insulated transmission of the first signal; a second coupler that performs insulated transmission of the second signal; an output ground terminal; an output terminal from which a gate driving signal to be applied to the switching element is outputted; a startup switch which is provided between a gate voltage source and the output terminal, and includes one or more transistors; a termination switch which is provided between the output terminal and the output ground terminal, and includes one or more transistors; a startup resistor provided between a gate and a source of a transistor among the one or more transistors included in the startup switch; a termination resistor provided between a gate and a source of a transistor among the one or more transistors included in the termination switch; a first rectifier that rectifies an output of the first coupler, and outputs a voltage for driving the startup switch; and a second rectifier that rectifies an output of the second coupler, and outputs a voltage for driving the termination switch. In the gate driving circuit, the transmission circuit is configured to adjust, from among the first signal and the second signal, at least a smaller amplitude among the binary-modulated amplitudes.

Accordingly, in the gate driving circuit, the adjustment of a smaller amplitude of the first signal makes it possible to adjust the startup time of the gate driving signal. Conversely, the adjustment of a smaller amplitude of the second signal makes it possible to adjust the termination time of the gate driving signal. Therefore, without providing a gate resistor between the gate driving circuit and the switching element, it is possible to adjust the slew rate of the switching element at the time of switching on and off the switching element.

In the gate driving circuit according to the second aspect or the third aspect of the present disclosure, the first coupler and the second coupler may be electromagnetic field resonance couplers.

In addition, a power switching system according to an aspect of the present disclosure includes: a switching element; and the gate driving circuit according to any one of the first aspect to the third aspect of the present disclosure which controls the switching element. In the power switching system, the output terminal in the gate driving circuit is connected with a gate of the switching element, not via a gate resistor.

Hereinafter, embodiments will be described in detail with reference to the drawings.

Note that the embodiments below each describe a general or specific example. The numerical values, shapes, materials, structural elements, the arrangement and the connection of the structural elements, steps, the processing order of the steps etc. illustrated in the following embodiments are mere examples, and are not intended to limit the present disclosure. Among the structural elements in the following embodiments, those not recited in any of the independent claims representing the most generic concepts are described as optional structural elements.

### Embodiment 1

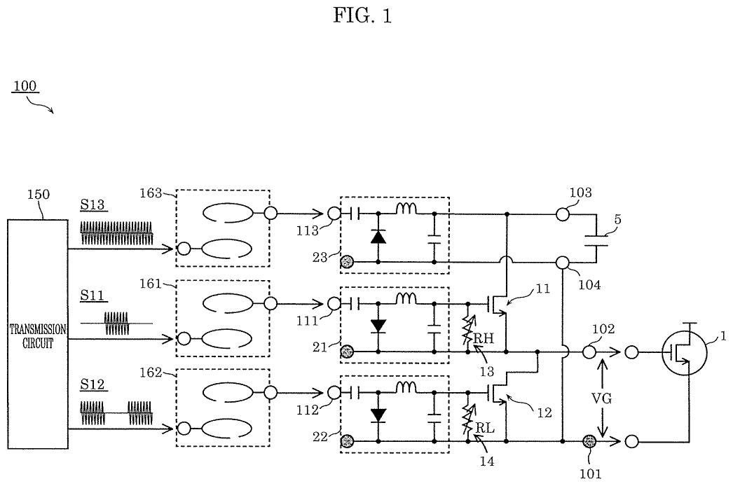

FIG. 1 is a diagram illustrating a configuration example of a power switching system which includes gate driving circuit 100 according to Embodiment 1. The configuration illustrated in FIG. 1 performs non-contact electric power transmission. Gate driving circuit 100 illustrated in FIG. 1 applies gate voltage VG (gate driving signal) to the gate of switching element 1 which can withstand high voltage to switch on and off switching element 1. Switching element 1 is the so-called power device. Gate driving circuit 100 includes: output ground terminal 101; output terminal 102 from which gate voltage VG is outputted; and gate voltage source terminals 103 and 104. Output terminal 102 is connected to the gate of switching element 1 which is driving, and output ground terminal 101 is connected to the source of switching element 1. Capacitor 5 which is a gate voltage source is connected to gate voltage source terminals 103 and 104.

In the configuration illustrated in FIG. 1, a gate resistor is not provided between gate driving circuit 100 and switching element 1. That is to say, output terminal 102 in gate driving circuit 100 is connected with the gate of switching element 1, not via the gate resistor.

In addition, gate driving circuit 100 includes startup switch 11, termination switch 12, first rectifier 21, second rectifier 22, third rectifier 23, transmission circuit 150, first coupler 161, second coupler 162, and third coupler 163.

Here, startup switch 11 and termination switch 12 each include a normally-on type transistor. As for startup switch 11, the drain is connected with gate voltage source terminal 103, and the source is connected with output terminal 102. As for termination switch 12, the drain is connected with output terminal 102, and the source is connected with output ground terminal 101. The normally-on type transistor allows a current to flow between the drain and the source of the normally-on type transistor when a gate voltage is 0 V, because the resistance between the drain and the source becomes low. In order to stop the current from flowing between the drain and the source, a negative voltage is to be applied to the gate of the normally-on type transistor. Note that startup switch 11 and termination switch 12 each may include a transistor other than the normally-on type transistor.

First rectifier 21, second rectifier 22, and third rectifier 23 each are a circuit which rectifies a high frequency signal inputted, and generate electric power and a voltage which are rectified. First rectifier 21 outputs a voltage for driving startup switch 11, and second rectifier 22 outputs a voltage for driving termination switch 12. Here, first rectifier 21 supplies a negative voltage for switching off startup switch 11, when the output of first rectifier 21 is connected to the gate of startup switch 11, and a high frequency signal is inputted to input terminal 111. Second rectifier 22 supplies a negative voltage for switching off termination switch 12, when the output of second rectifier 22 is connected to the gate of termination switch 12, and a high frequency signal is inputted to input terminal 112. As for third rectifier 23, electric power is supplied to capacitor 5 which is connected to gate voltage source terminals 103 and 104, when the output is connected to gate voltage source terminals 103 and 104, and a high frequency signal is inputted to input terminal 113. Capacitor 5 that has been charged serves as a gate voltage source.

Here, first rectifier 21, second rectifier 22, and third rectifier 23 each are a single-shunt type rectifier which includes two capacitors, an inductor, and a diode. For instance, in first rectifier 21, a first capacitor and the inductor are inserted in series between the input and the output of first rectifier 21. Also, the anode of the diode is connected between the first capacitor and the inductor, and the cathode of the diode is connected to the ground. A second capacitor is connected between another end of the inductor and the ground. First rectifier 21 and second rectifier 22 have the same configuration. Third rectifier 23 has the same configuration as first rectifier 21, except that the direction of the diode is different. Note that first rectifier 21, second rectifier 22, and third rectifier 23 each are not limited to a rectifier of a single-shunt type, and may be a rectifier of a voltage doubler type, a double current type, a single series type, and the like.

In addition, startup resistor 13 is provided between the gate and the source of startup switch 11, and termination resistor 14 is provided between the gate and the source of termination switch 12. In the present disclosure, startup resistor 13 and termination resistor 14 are configured to adjust a resistance value. Specifically, startup resistor 13 and termination resistor 14 each include a variable resistor.

Transmission circuit 150 outputs first signal S11, second signal S12, and third signal S13 which are high frequency signals. As for first signal S11 and second signal S12, the amplitudes are modulated (binary modulation) between the on state and the off state. When first signal S11 and second signal S12 are in the on state, first signal S1 1 and second signal S12 output a continuous signal, and conversely, when first signal S11 and second signal S12 are in the off state, first signal S11 and second signal S12 do not output a continuous signal. Furthermore, the on state and the off state of first signal S11 and second signal S12 are complementary to each other. Third signal S13 is an unmodulated continuous wave. Note that the frequency of a high frequency signal is to be, for example, 2.4 GHz here. However, the high frequency signal may have a different frequency.

First coupler 161, second coupler 162, and third coupler 163 each are a transmission element which transmits a high frequency signal, and of which the input and the output are isolated. First coupler 161, second coupler 162, and third coupler 163 each can be realized by an electromagnetic field resonance coupler. In first coupler 161, second coupler 162, and third coupler 163, a direct current component is isolated (isolation of a signal ground) between the input and the output. Pressure resistance of first coupler 161, second coupler 162, and third coupler 163 is at least 1 kV, for example. First signal S11 is inputted to first rectifier 21 via first coupler 161. Second signal S12 is inputted to second rectifier 22 via second coupler 162. Third signal S13 is inputted to third rectifier 23 via third coupler 163.

When first signal S11 is in the on state, first rectifier 21 rectifies a high frequency signal inputted to output a negative voltage. When second signal S12 is in the on state, second rectifier 22 rectifies a high frequency signal inputted to output a negative voltage. Third rectifier 23 receives a high frequency signal which is third signal S13, and outputs a positive voltage. The positive voltage outputted from third rectifier 23 is applied to capacitor 5.

(Operation)

Operation performed by the configuration illustrated in FIG. 1 will be described. When first signal S11 is in the on state, first rectifier 21 supplies a negative voltage to the gate of startup switch 11 to switch off startup switch 11. At this time, second signal S12 is in the off state, and thus second rectifier 22 does not output electric power. Accordingly, termination switch 12 is in the on state, because the gate of termination switch 12 is short-circuited by termination resistor 14. In this condition, output terminal 102 and output ground terminal 101 are short-circuited by termination switch 12, and thus there will be no output from gate driving circuit 100, and switching element 1 is switched off. In addition, third rectifier 23 at this time receives third signal S13, supplies a positive voltage to gate voltage source terminals 103 and 104, and stores electric power in capacitor 5.

Next, operation performed by gate driving circuit 100 to bring switching element 1 into the on state from the off state will be described.

When second signal S12 is brought into the on state and a high frequency signal is inputted to second rectifier 22, second rectifier 22 generates a negative voltage. The negative voltage is applied to the gate of termination switch 12, and thus termination switch 12 is brought into the off state. At this time, electric power generated in second rectifier 22 is used for charging the gate of termination switch 12, and as electric power to flow through termination resistor 14. That is to say, when the resistance value of termination resistor 14 is small (for example, hundreds of ohms), termination resistor 14 consumes the most of electric power, and a voltage is not applied to the gate of termination switch 12. Because of this, it requires a long time before termination switch 12 is brought into the off state. On the contrary, when the resistance value of termination resistor 14 is great (for example, several kilo-ohms), termination resistor 14 only consumes a small amount of electric power, and thus termination switch 12 is immediately brought into the off state.

In addition, since first signal S11 is in the off state at this time, first rectifier 21 does not output electric power. Because of this, the gate of startup switch 11 is short-circuited via startup resistor 13, and thus startup switch 11 is brought into the on state, or in other words, a state in which a current flows through startup switch 11. At this time, gate charges of startup switch 11 annihilate via startup resistor 13. However, when the resistance value of startup resistor 13 is great (for example, several kilo-ohms), gate charges annihilate slowly, and thus startup switch 11 is slowly brought into the on state. On the contrary, when the resistance value of startup resistor 13 is small (for example, hundreds of ohms), startup switch 11 is immediately brought into the on state, and a current begins to flow through startup switch 11.

When startup switch 11 is brought into the on state, capacitor 5 which is connected to gate voltage source terminals 103 and 104 applies gate voltage VG to the gate of switching element 1 via startup switch 11. This brings switching element 1 into the on state. At this time, the amount of a current which flows through startup switch 11 is determined by the resistance value of startup resistor 13, and the current which flows through startup switch 11 determines the speed for switching on switching element 1, or in other words, the turn-on time. As such, the resistance value of startup resistor 13 determines the slew rate of switching element 1 at the time of switching on switching element 1.

Now, the timing at which startup switch 11 and termination switch 12 are brought into the on state from the off state, and vice versa, is important, because this timing also affects the slew rate of switching operation. For example, if it takes a long time to bring termination switch 12 into the off state from the on state, the most of electric power stored in capacitor 5 that serves as a gate voltage source is consumed from output ground terminal 101 via termination switch 12, without being used for driving switching element 1. Next, operation performed by gate driving circuit 100 to bring switching element 1 into the off state from the on state will be described.

When first signal S11 is brought into the on state and a high frequency signal is inputted to first rectifier 21, first rectifier 21 generates a negative voltage. The negative voltage is applied to the gate of startup switch 11, and thus startup switch 11 is brought into the off state. When the resistance value of startup resistor 13 is great at this time (for example, several kilo-ohms), startup switch 11 is slowly brought into the off state, and conversely, when the resistance value of startup resistor 13 is small (for example, hundreds of ohms), startup switch 11 is immediately brought into the off state.

In addition, second signal S12 is brought into the off state, and second rectifier 22 stops generating a negative voltage at this time. With this, the gate of termination switch 12 is short-circuited via termination resistor 14, and termination switch 12 is brought into the on state. When the resistance value of termination resistor 14 is great at this time (for example, several kilo-ohms), termination switch 12 is slowly brought into the on state, and conversely, when the resistance value of termination resistor 14 is small (for example, hundreds of ohms), termination switch 12 is immediately brought into the on state.

This short-circuits output ground terminal 101 and output terminal 102, and switching element 1 is brought into the off state. When termination switch 12 is slowly brought into the on state, a small current flows through termination switch 12, and gate charges slowly annihilate, and thus switching element 1 is slowly brought into the off state. Conversely, when termination switch 12 is immediately brought into the on state, a large current flows through termination switch 12, and switching element 1 is quickly brought into the off state. As such, the resistance value of termination resistor 14 determines the current that flows through termination switch 12. The current that flows through termination switch 12 determines the turn-off time of switching element 1, or in other words, the slew rate of switching element 1 at the time of switching off switching element 1, to determine the speed for discharging gate charges accumulated in switching element 1.

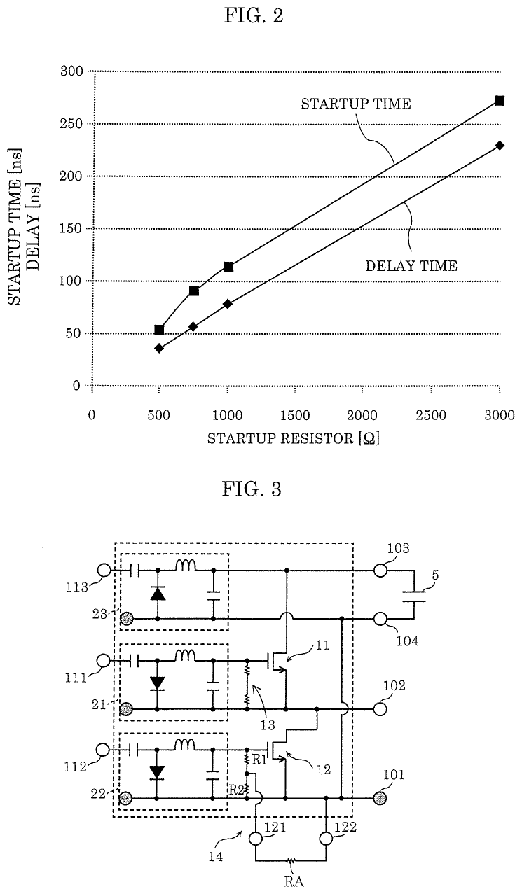

FIG. 2 shows an example of measurement data obtained by the inventors of the present application. FIG. 2 is a graph illustrating a relation between a resistance value of startup resistor 13, startup time of switching element 1, and delay time of switching element 1. As shown in FIG. 2, the adjustment of a resistance value of startup resistor 13 makes it possible to shorten the startup time of switching element 1, and increase the slew rate of switching element 1 at the time of switching on switching element 1 or, conversely, lengthen the startup time of switching element 1, and decrease the slew rate of switching element 1 at the time of switching on switching element 1. Similarly, the adjustment of a resistance value of startup resistor 13 makes it possible to adjust the delay time. The delay time here is the time it takes for an input signal inputted in gate driving circuit 100 to be outputted from gate driving circuit 100 as an output signal.

As has been described in the embodiment, the resistance value of startup resistor 13 which is provided between the gate and the source of startup switch 11, and the resistance value of termination resistor 14 which is provided between the gate and the source of termination switch 12 are adjustable. This makes it possible to shorten or lengthen the startup time and the termination time of gate driving signal VG to be applied to switching element 1. Therefore, it is possible to adjust the slew rate of switching element 1 at the time of switching on and switching off switching element 1, without providing a gate resistor between a gate driving circuit and a switching element which has been provided in conventional configurations.

Note that the configuration illustrated in FIG. 1 allows the adjustment of resistance values for both startup resistor 13 and termination resistor 14; however, the configuration may allow the adjustment of a resistance value for either startup resistor 13 or termination resistor 14. When the resistance value of startup resistor 13 is adjustable, it is possible to adjust the slew rate of switching element 1 at the time of switching on switching element 1. In addition, when the resistance value of termination resistor 14 is adjustable, it is possible to adjust the slew rate of switching element 1 at the time of switching off switching element 1.

### VARIATIONS

### Variation 1

FIG. 3 is a schematic diagram illustrating another configuration example of a startup resistor and a termination resistor. In FIG. 3, the configuration of termination resistor 14 which allows the adjustment of a resistance value is different from the configuration illustrated in FIG. 1. That is, resistances R1 and R2 are connected in series between the gate and the source of termination switch 12 in the configuration illustrated in FIG. 3. In addition, external terminals 121 and 122 are provided so that external resistor RA can be connected between a connecting end between resistances R1 and R2, and output ground terminal 101. With this configuration, the resistance value of termination resistor 14 is a resistance value of combined resistance of resistances R1 and R2 and external resistor RA. That is to say, the resistance value of termination resistor 14 can be adjusted by the selection of external resistor RA.

Note that when external terminals 121 and 122 are provided for connecting external resistor RA as in the configuration illustrated in FIG. 3, a gate voltage of termination switch 12 can be monitored from these external terminals 121 and 122. Based on the gate voltage monitored, it is possible to select external resistor RA, and to change the value of resistance RA at any time.

Note that in the configuration illustrated in FIG. 3, startup resistor 13 is a fixed resistor. However, startup resistor 13 may be configured to adjust a resistance value. In this case, the configuration may include a variable resistor as illustrated in FIG. 1, or may allow a resistance value to be adjustable by selecting an external resistor, like termination resistor 14 illustrated in FIG. 3.

### Variation 2

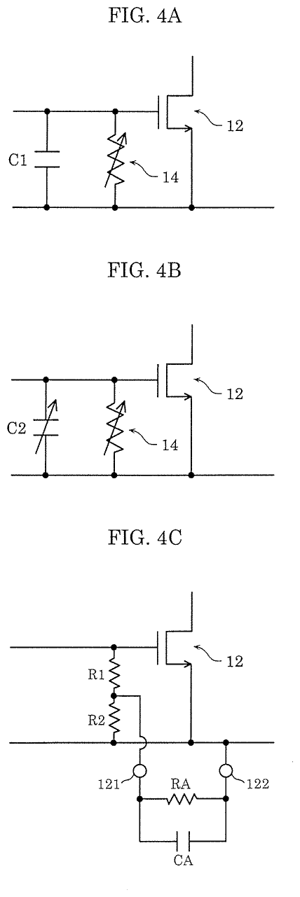

A capacitor may be provided in parallel with startup resistor 13 or termination resistor 14. FIG. 4A, FIG. 4B, and FIG. 4C each illustrate a configuration example in which a capacitor is connected in parallel with termination resistor 14. In FIG. 4A, capacitor C1 whose capacitance value is fixed is provided in parallel with termination resistor 14. In FIG. 4B, capacitor C2 whose capacitance value is variable is provided in parallel with termination resistor 14. In FIG. 4C, external resistor RA is provided in parallel with capacitor CA in termination resistor 14 illustrated in FIG. 3. The configurations illustrated in FIG. 4B and FIG. 4C allow the adjustment of a resistance value of termination resistor 14, in addition to a capacitance value.

### Variation 3

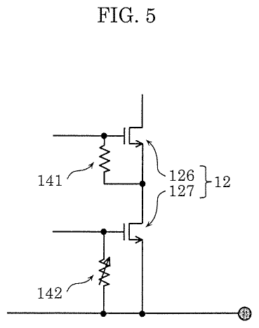

Startup switch 11 or termination switch 12 may include a plurality of transistors which are connected in series. FIG. 5 illustrates another configuration example of termination switch 12. In FIG. 5, termination switch 12 includes transistors 126 and 127 which are vertically stacked. Fixed resistor 141 is provided between the gate and the source of transistor 126, and variable resistor 142 is provided between the gate and the source of transistor 127. As such, a transistor among the plurality of transistors of which a switch is configured of as described above may be configured to adjust the resistance value of a resistor provided between the gate and the source.

### Variation 4

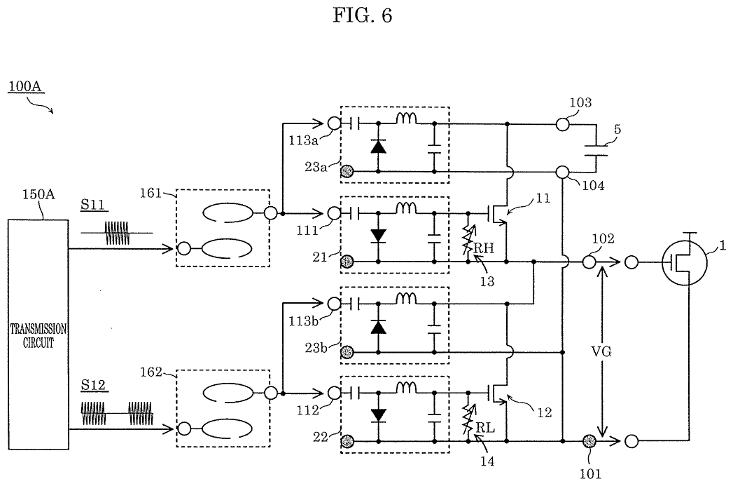

FIG. 6 illustrates a variation of the configuration illustrated in FIG. 1. In the configuration illustrated in FIG. 6, transmission circuit 150A does not output third signal S13, and third coupler 163 is omitted from gate driving circuit 100A. Gate driving circuit 100A includes rectifiers 23a and 23b, instead of third rectifier 23. As for rectifier 23a, input terminal 113a receives the output of first coupler 161. When first signal S11 is in the on state, rectifier 23a rectifies a high frequency signal inputted to output a positive voltage. As for rectifier 23b, input terminal 113b receives the output of second coupler 162. When second signal S12 is in the on state, rectifier 23b rectifies a high frequency signal inputted to output a positive voltage. The positive voltages outputted from rectifiers 23a and 23b are applied to capacitor 5. The configuration illustrated in FIG. 6 produces the same effects as the configuration illustrated in FIG. 1.

### Variation 5

The above embodiments describe examples of configurations which perform non-contact electric power transmission; however, the present disclosure is applicable to other configurations.

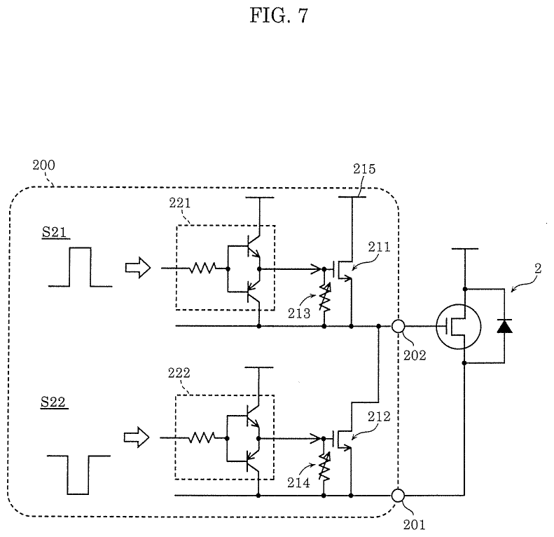

FIG. 7 illustrates a configuration example of a gate driving circuit whose configuration performs other than the non-contact electric power transmission. Gate driving circuit 200 illustrated in FIG. 7 applies a gate voltage to the gate of switching element 2 to switch on and off switching element 2. Gate driving circuit 200 includes output ground terminal 201, and output terminal 202 from which a gate voltage is outputted. Output terminal 202 is connected to the gate of switching element 2 which is driving, and output ground terminal 201 is connected to the source of switching element 2. A gate resistor is not provided between gate driving circuit 200 and switching element 2.

In addition, gate driving circuit 200 includes startup switch 211, termination switch 212, first driving circuit 221, and second driving circuit 222. As for startup switch 211, the drain is connected with gate voltage source 215, and the source is connected with output terminal 202. As for termination switch 212, the drain is connected with output terminal 202, and the source is connected with output ground terminal 201. As for first driving circuit 221, the output is connected to the gate of startup switch 211, and receives startup signal S21 as an input. As for second driving circuit 222, the output is connected to the gate of termination switch 212, and receives termination signal S22 as an input.

Startup resistor 213 is provided between the gate and the source of startup switch 211, and termination resistor 214 is provided between the gate and the source of termination switch 212. Here, like the embodiments described above, startup resistor 213 and termination resistor 214 are configured to adjust a resistance value. Specifically, startup resistor 213 and termination resistor 214 each include a variable resistor.

The configuration illustrated in FIG. 7 produces the same effects as the configurations described in the above embodiments. That is to say, the adjustment of resistance values of startup resistor 213 and termination resistor 214 makes it possible to shorten and lengthen the startup time and the termination time of a gate voltage to be applied to switching element 2. Therefore, it is possible to adjust the slew rate of switching element 2 at the time of switching on and switching off switching element 2, without providing a gate resistor between a gate driving circuit and a switching element which has been provided in conventional configurations.

### Variation 6

In addition, startup switch 11 and termination switch 12 each may be either a p-type metal-oxide-semiconductor field-effect transistors (MOSFET) or an N-type MOSFET, for example. A pull down resistor which is connected to the p-type MOSFET is connected between the gate and the source.

### Embodiment 2

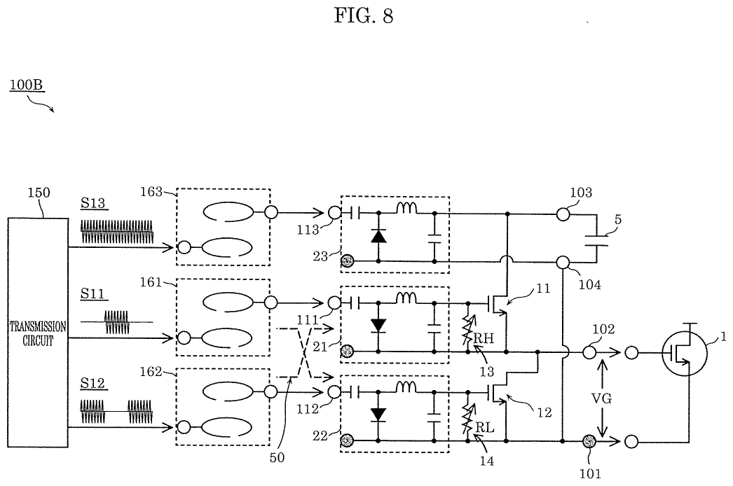

FIG. 8 is a diagram illustrating a configuration example of a power switching system which includes a gate driving circuit according to Embodiment 2. The configuration illustrated in FIG. 8 has substantially the same configuration illustrated in FIG. 1. Thus, common structural elements are given the same reference signs as FIG. 1, and detailed descriptions for those common structural elements may be omitted here.

Gate driving circuit 100B illustrated in FIG. 8 includes crosstalk quantity adjuster 50 which adjusts the crosstalk quantity between first coupler 161 and second coupler 162. Crosstalk quantity adjuster 50 enables the adjustment of a crosstalk quantity between first coupler 161 and second coupler 162, or in other words, the adjustment of the degree of isolation between signal transmission performed by first coupler 161 and signal transmission performed by second coupler 162. Crosstalk quantity adjuster 50 is realized by, for example, a capacitor, reflecting plate, etc.

With this configuration, the most of the output of first coupler 161 is inputted in first rectifier 21, but some of the output is inputted in second rectifier 22 according to the crosstalk quantity adjusted by crosstalk quantity adjuster 50. Conversely, the most of the output of second coupler 162 is inputted in second rectifier 22, but some of the output is inputted in first rectifier 21 according to the crosstalk quantity adjusted by crosstalk quantity adjuster 50.

When first signal S11 is in the off state and startup switch 11 is in the on state, a small amount of electric power is supplied to the gate of startup switch 11, based on the electric power corresponding to a crosstalk quantity. This increases the on-resistance of startup switch 11, and thus a current that flows through startup switch 11 is smaller than a current that flows through startup switch 11 when startup switch 11 is in a normal on state. Similarly, when second signal S12 is in the off state and termination switch 12 is in the on state, a small amount of electric power is supplied to the gate of termination switch 12, based on the electric power corresponding to a crosstalk quantity. This increases the on-resistance of termination switch 12, and thus a current that flows through termination switch 12 is smaller than a current that flows through termination switch 12 when termination switch 12 is in a normal on state.

Therefore, it is possible for crosstalk quantity adjuster 50 to adjust the startup time and the termination time of gate voltage VG which is to be applied to switching element 1 by adjusting the crosstalk quantity between first coupler 161 and second coupler 162. That is to say, crosstalk quantity adjuster 50 enables the adjustment of the slew rate at the time of switching on and switching off switching element 1.

Note that startup resistor 13 and termination resistor 14 each need not have a configuration which enables the adjustment of a resistance value in the embodiment.

### Embodiment 3

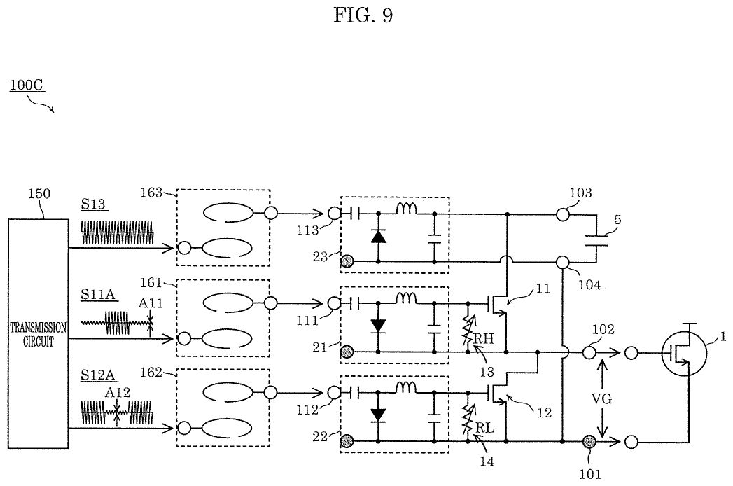

FIG. 9 is a schematic diagram illustrating a configuration of a power switching system which includes a gate driving circuit according to Embodiment 3. The configuration illustrated in FIG. 9 has substantially the same configuration illustrated in FIG. 1. Thus, common structural elements are given the same reference signs as FIG. 1, and detailed descriptions for those common structural elements may be omitted here.

In gate driving circuit 100C illustrated in FIG. 9, transmission circuit 150 outputs, as first signal S11A, a high frequency signal including amplitude All that is small when first signal 11A is in the off state. In addition, transmission circuit 150 outputs, as second signal S12A, a high frequency signal including amplitude A12 that is small when second signal S12A is in the off state.

Due to such first signal S11A, a small amount of electric power is supplied to the gate of startup switch 11 when first signal S11A is in the off state and startup switch 11 is in the on state. This increases the on-resistance of startup switch 11, and thus a current that flows through startup switch 11 is smaller than a current that flows through startup switch 11 when startup switch 11 is in a normal on state. Similarly, a small amount of electric power is supplied to the gate of termination switch 12 when second signal S12A is in the off state and termination switch 12 is in the on state. This increases the on-resistance of termination switch 12, and thus a current that flows through termination switch 12 is smaller than a current that flows through termination switch 12 when termination switch 12 is in a normal on state.

Therefore, it is possible for transmission circuit 150 to adjust the startup time and the termination time of gate voltage VG which is to be applied to switching element 1 by adjusting amplitude A11 of first signal S11A and amplitude A12 of second signal S11B. That is to say, it is possible to adjust the slew rate of switching element 1 at the time of switching on and switching off switching element 1 according to the output of transmission circuit 150.

Note that in the embodiment, transmission circuit 150 adjusts the amplitudes of both first signal S11A and second signal SUB when first signal S11A and second signal S11B are in the off state; however, transmission circuit 150 may adjust the amplitude of either first signal S11A or second signal SUB when first signal S11A or second signal SUB is in the off state. In addition, startup resistor 13 and termination resistor 14 each need not have a configuration which enables the adjustment of a resistance value.

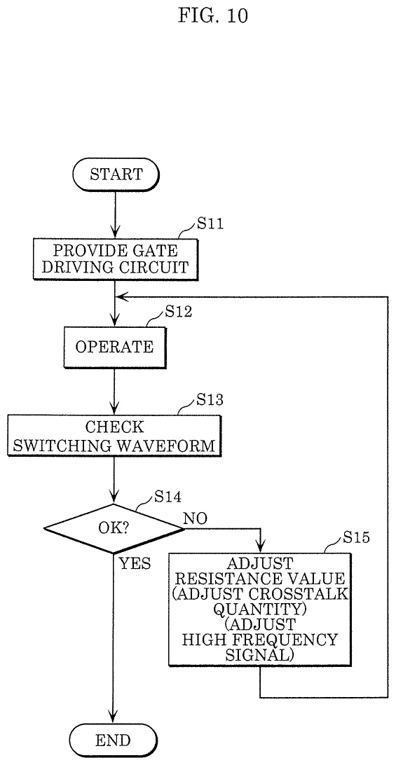

FIG. 10 is a flowchart illustrating a method of adjusting the slew rate at the time of switching operation performed by the switching element having the configuration that includes gate driving circuits which have been described in respective embodiments described above. First, provide a gate driving circuit for a predetermined device, such as a vehicle (S11). Then, operate the gate driving circuit (S12), and check the switching waveform of the switching element (S13). When the slew rate at the time of switching operation satisfies a predetermined condition (YES in S14), finish processing. When the slew rate does not satisfy the predetermined condition (NO in S14), adjust the resistance values of startup resistor 13 and termination resistor 14, if the gate driving circuit is the driving circuit according to Embodiment 1 (S15). Then, operate the gate driving circuit again, and check the switching waveform of the switching element (S12 and S13).

Note that in step S15, if the gate driving circuit is the gate driving circuit according to Embodiment 2, crosstalk quantity adjuster 50 may adjust a crosstalk quantity. Furthermore, if the gate driving circuit is the gate driving circuit according to Embodiment 3, adjust amplitude All and amplitude A12 of high frequency signals which are the output of transmission circuit 150.

Although only some exemplary embodiments of the present disclosure have been described in detail above, those skilled in the art will readily appreciate that many modifications are possible in the exemplary embodiments without materially departing from the novel teachings and advantages of the present disclosure. Accordingly, all such modifications are intended to be included within the scope of the present disclosure.

### INDUSTRIAL APPLICABILITY

Since the gate driving circuit according to the a present disclosure makes it possible to adjust the slew rate at the time of switching operation without providing a gate resistor, it is useful for downsizing a power switching system, for example.

What is claimed is:

1. A gate driving circuit that controls a switching element, the gate driving circuit comprising:
an output ground terminal;
an output terminal from which a gate driving signal to be applied to the switching element is outputted;
a startup switch which is provided between a gate voltage source and the output terminal, and includes one or more transistors;
a termination switch which is provided between the output terminal and the output ground terminal, and includes one or more transistors;
a startup resistor provided between a gate and a source of a transistor among the one or more transistors included in the startup switch; and
a termination resistor provided between a gate and a source of a transistor among the one or more transistors included in the termination switch, wherein
at least one of the startup resistor or the termination resistor is configured to adjust a resistance value.

2. The gate driving circuit according to claim 1, wherein
at least one of the startup resistor or the termination resistor includes a variable resistor.

3. The gate driving circuit according to claim 1, wherein
at least one of the startup resistor or the termination resistor is configured to accept an external resistor.

4. The gate driving circuit according to claim 1, further comprising:
a capacitor in parallel with at least one of the startup resistor or the termination resistor.

5. A gate driving circuit that controls a switching element, the gate driving circuit comprising:
a transmission circuit that transmits a first signal and a second signal which are high frequency signals, and have binary-modulated amplitudes, the first signal and the second signal being complementarily modulated;
a first coupler that performs insulated transmission of the first signal;
a second coupler that performs insulated transmission of the second signal;
an output ground terminal;
an output terminal from which a gate driving signal to be applied to the switching element is outputted;
a startup switch which is provided between a gate voltage source and the output terminal, and includes one or more transistors;
a termination switch which is provided between the output terminal and the output ground terminal, and includes one or more transistors;
a startup resistor provided between a gate and a source of a transistor among the one or more transistors included in the startup switch;
a termination resistor provided between a gate and a source of a transistor among the one or more transistors included in the termination switch;
a first rectifier that rectifies an output of the first coupler, and outputs a voltage for driving the startup switch;
a second rectifier that rectifies an output of the second coupler, and outputs a voltage for driving the termination switch; and
a crosstalk quantity adjuster that adjusts a crosstalk quantity between the first coupler and the second coupler.

6. A gate driving circuit that controls a switching element, the gate driving circuit comprising:
a transmission circuit that transmits a first signal and a second signal which are high frequency signals, and have binary-modulated amplitudes, the first signal and the second signal being complementarily modulated;
a first coupler that performs insulated transmission of the first signal;
a second coupler that performs insulated transmission of the second signal;
an output ground terminal;
an output terminal from which a gate driving signal to be applied to the switching element is outputted;
a startup switch which is provided between a gate voltage source and the output terminal, and includes one or more transistors;
a termination switch which is provided between the output terminal and the output ground terminal, and includes one or more transistors;
a startup resistor provided between a gate and a source of a transistor among the one or more transistors included in the startup switch;
a termination resistor provided between a gate and a source of a transistor among the one or more transistors included in the termination switch;
a first rectifier that rectifies an output of the first coupler, and outputs a voltage for driving the startup switch; and
a second rectifier that rectifies an output of the second coupler, and outputs a voltage for driving the termination switch, wherein
the transmission circuit is configured to adjust, from among the first signal and the second signal, at least a smaller amplitude among the binary-modulated amplitudes.

7. The gate driving circuit according to claim 5, wherein
the first coupler and the second coupler are electromagnetic field resonance couplers.

8. The gate driving circuit according to claim 6, wherein
the first coupler and the second coupler are electromagnetic field resonance couplers.

9. A power switching system, comprising:
a switching element; and
the gate driving circuit according to claim 1 which controls the switching element, wherein
the output terminal in the gate driving circuit is connected with a gate of the switching element, not via a gate resistor.
